(19) United States
(12) Patent Application Publication
(10) Pub. No.: US 2024/0322679 A1
(43) Pub. Date: Sep. 26, 2024

(54) DC-DC CONVERTER

(71) Applicant: ABLIC Inc., Nagano (JP)

(72) Inventor: Minoru SUDO, Nagano (JP)

(73) Assignee: ABLIC Inc., Nagano (JP)

(21) Appl. No.: 18/607,583

(22) Filed: Mar. 18, 2024

(30) Foreign Application Priority Data
Mar. 24, 2023 (JP) 2023-048688

(51) Int. Cl. H02M 3/07

(52) U.S. Cl. CPC H02M 3/07

(57) ABSTRACT

A DC-DC converter is provided. The DC-DC converter includes terminals; a charge pump circuit including an oscillation circuit and provided between the terminal and the terminal; a comparison circuit including a comparator that has a hysteresis characteristic and outputs an oscillation on-off control signal that controls switching between ON and OFF of the oscillation operation of the oscillation circuit based on a magnitude relationship between a voltage proportional to the output voltage between the terminals and a first reference voltage; and a comparison circuit that outputs a control signal that controls the oscillation operation of the oscillation circuit based on a voltage proportional to the input voltage between the terminals and a second reference voltage.

### CROSS-REFERENCE TO RELATED APPLICATION

This application claims the priority benefits of Japanese application no. 2023-048688, filed on Mar. 24, 2023. The entirety of the above-mentioned patent application is hereby incorporated by reference herein and made a part of this specification.

### BACKGROUND

### Technical Field

The present invention relates to a DC-DC converter.

### Related Art

Direct Current to Direct Current (DC-DC) converters are used to efficiently transmit power from power sources whose output is unstable due to fluctuations in the surrounding environment such as light, heat, and pressure. For example, there is a DC-DC converter that operates at maximum power conversion efficiency using a solar cell that converts light energy into electrical energy as an energy source.

As an example of a DC-DC converter that operates at maximum power conversion efficiency using a solar cell as an energy source, the maximum power point tracking device (hereinafter referred to as “tracker”) of a solar cell includes a microcontroller. The microcontroller controls the duty ratio (on-off ratio of a switching element) of a switching regulator, which is an example of a DC-DC converter, such that the input power is maximized.

To explain in more detail, in the case where there is an increase or decrease in input power, the microcontroller calculates the amount of increase or decrease necessary for controlling the duty ratio of the switching regulator to an appropriate value according to the increase or decrease, generates a control signal for controlling to the calculated duty ratio, and supplies the generated control signal to a control terminal of the switching element. By controlling the on and off of the switching element, the duty ratio of the switching regulator is controlled.

### SUMMARY

A conventional DC-DC converter operating at maximum power conversion efficiency includes a microcontroller in order to achieve control for operation at maximum power conversion efficiency, as described above. Since the power consumption during operation of the microcontroller is covered by the power supplied to the DC-DC converter, it is difficult to covert power with high efficiency. Moreover, the conventional DC-DC converter cannot not be used for devices that supply power less than the power consumption of the microcontroller.

The present invention provides a DC-DC converter capable of high efficiency power conversion even when a small amount of power, such as less than the power consumption of the microcontroller, is supplied.

A DC-DC converter according to the present invention is a DC-DC converter including a first input terminal, a second input terminal, a first output terminal, and a second output terminal; a charge pump circuit including an oscillation circuit and provided between the first input terminal and the first output terminal; a first control circuit including a first comparator that has a hysteresis characteristic and outputs a signal including two signal levels based on a magnitude relationship between a voltage proportional to an output voltage between the first output terminal and the second output terminal and a first reference voltage, generating a first control signal that controls switching of the signal between ON and OFF of an oscillation operation of the oscillation of the oscillation circuit; and a second control circuit outputting a signal based on a voltage proportional to an input voltage between the first input terminal and the second input terminal and a second reference voltage as a second control signal that controls the oscillation operation of the oscillation circuit.

According to the present invention, power conversion at high efficiency is possible even if the power supplied is small, such as less than the power consumption during operation of the microcontroller. Moreover, according to the present invention, since the circuit may be configured without including a coil, it is possible to integrate and thus miniaturize this circuit.

### BRIEF DESCRIPTION OF THE DRAWINGS

FIG. 1 is an explanatory diagram illustrating an application example of a DC-DC converter according to an embodiment of the present invention.

FIG. 2 is a circuit diagram of a DC-DC converter according to a first embodiment.

FIG. 3 is a circuit diagram illustrating an example of a comparison circuit included in the DC-DC converter according to the first embodiment.

FIG. 4 is a characteristic diagram illustrating current versus voltage (voltage-current characteristic) for a single-cell solar cell.

FIG. 5 is a circuit diagram of a DC-DC converter according to a second embodiment.

FIG. 6 is a circuit diagram illustrating an example of an oscillation control circuit included in the DC-DC converter according to the second embodiment.

FIG. 7 is a circuit diagram illustrating an example of an error amplification circuit included in the DC-DC converter according to the second embodiment.

### DESCRIPTION OF THE EMBODIMENTS

Hereinafter, a DC-DC converter according to an embodiment of the present invention will be described with reference to the drawings.

### First Embodiment

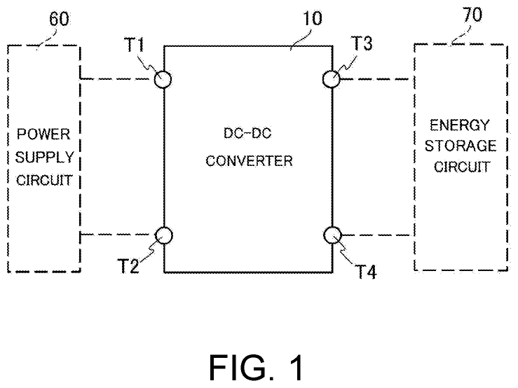

FIG. 1 is a schematic diagram illustrating an application example of a DC-DC converter 10, which is an example of the DC-DC converter according to a first embodiment of the present invention.

The DC-DC converter 10 includes a terminal T1 and a terminal T2, which are terminals on a primary (input) side, and a terminal T3 and a terminal T4, which are terminals on a secondary (output) side. For example, a power supply circuit 60, which serves as a supply source of power, is connected to the terminal T1 and the terminal T2. The connected power supply circuit 60 is a device capable of supplying power that includes a power generation element whose relationship between the generated voltage and the output current (voltage-current characteristic) is known. An energy storage circuit 70, which includes a capacitive element that is capable of storing power and that serves as a supply destination of power, is connected to the terminal T3 and the terminal T4.

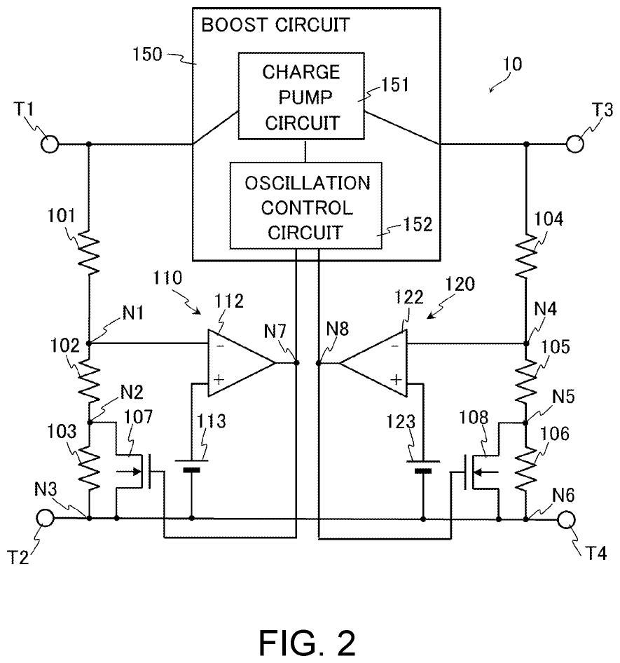

FIG. 2 is a circuit diagram of the DC-DC converter 10, which is an example of the DC-DC converter according to the first embodiment. Moreover, for each port of resistors 101 to 106 illustrated in FIG. 2, an upper port (on the side of the terminal T1 and the terminal T3) in the illustrated state is referred to as “first port”, and a lower port (on the side of the terminal T2 and the terminal T4) in the illustrated state is referred to as “second port”.

In addition to terminals T1 to T4, the DC-DC converter 10 further includes a charge pump circuit 151, an oscillation control circuit 152, a comparison circuit 110 as a second control circuit, and a comparison circuit 120 as a first control circuit. The terminal T2 is connected to the terminal T4. The charge pump circuit 151 and the oscillation control circuit 152 constitute a boost circuit 150.

Between the terminal T1 and the terminal T2, the resistor 101, the resistor 102, and the resistor 103 are connected in series from the terminal T1 to the terminal T2 to form a resistor voltage divider circuit. Moreover, between the terminal T3 and the terminal T4, the resistor 104, the resistor 105, and the resistor 106 are connected in series from the terminal T3 to the terminal T4 to form a resistor voltage divider circuit.

Here, the connection point between the resistor 101 and the resistor 102, the connection point between the resistor 102 and the resistor 103, the connection point between a second port of the resistor 103 and the terminal T2, the connection point between the resistor 104 and the resistor 105, the connection point between the resistor 105 and the resistor 106, and the connection point between a second port of the resistor 106 and the terminal T4 are referred to as a node N1, a node N2, a node N3, a node N4, a node N5, and a node N6 respectively.

A drain and a source of a NMOS (N-Metal-Oxide-Semiconductor) transistor 107, an example of a field-effect transistor (hereinafter referred to as “FET”), are connected to the node N2 and the node N3, respectively. Moreover, a drain and a source of a NMOS transistor 108 are connected to the node N5 and the node N6, respectively.

The comparison circuit 110 is a circuit that compares a magnitude of a voltage VN1 at the node N1, which is the connection point between the resistor 101 and the resistor 102, and a reference voltage Vref1, and outputs a first oscillation on-off control signal including two different signal levels (of the two, the one with higher signal level is referred to as “H level” and the lower one as “L level”) corresponding to the comparison result from an node N7, which is an output terminal.

The comparison circuit 110 includes a comparator 112 as a second comparator and a reference voltage circuit 113. The comparator 112 includes an inverting input terminal (−) connected to the node N1, a non-inverting input terminal (+) receiving supply of the reference voltage Vref1, and an output terminal connected to the node N7, which is an output terminal of the comparison circuit 110. The reference voltage circuit 113 includes an output port that is connected to the non-inverting input terminal (+) of the comparator 112 and supplies the reference voltage Vref1 as a second reference voltage to the non-inverting input terminal (+) of the comparator 112.

The comparison circuit 120 is a circuit that compares a magnitude of a voltage VN4 at the node N4, which is the connection point between the resistor 104 and the resistor 105, and a reference voltage Vref2, and outputs a second oscillation on-off control signal including two different signal levels (H level and L level) corresponding to the comparison result from an node N8, which is an output terminal.

The comparison circuit 120 includes a comparator 122 as a first comparator and a reference voltage circuit 123 as a first reference voltage circuit. The comparator 122 includes an inverting input terminal (−) connected to the node N4, a non-inverting input terminal (+) receiving supply of the reference voltage Vref2 as the first reference voltage, and an output terminal connected to the node N8, which is an output terminal of the comparison circuit 120. The reference voltage circuit 123 includes an output port that is connected to the non-inverting input terminal (+) of the comparator 122 and that supplies the reference voltage Vref2 to the non-inverting input terminal (+) of the comparator 122.

The charge pump circuit 151 includes an input port connected to the terminal T1, an output port connected to the terminal T3, and a control port receiving the oscillation control signal. The oscillation control circuit 152 includes a first input port connected to the node N7, a second input port connected to the node N8, and an output port connected to the control port of the charge pump circuit 151.

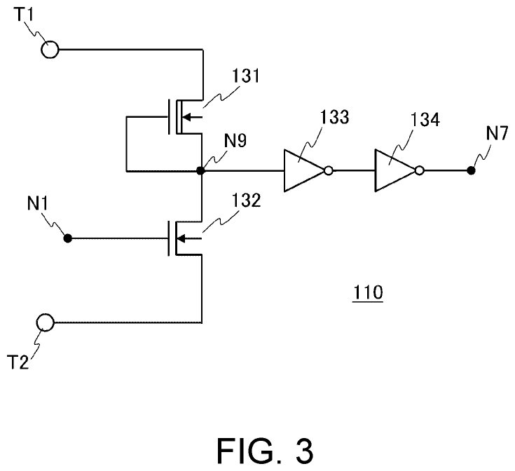

FIG. 3 is a circuit diagram illustrating a configuration example of the comparison circuit 110, which is an example of the comparison circuit included in the DC-DC converter according to the first embodiment.

The comparison circuit 110 is configured to include, for example, a depletion-type NMOS transistor 131, which is an example of a depletion-type FET, an enhancement-type NMOS transistor 132, which is an example of an enhancement-type FET (hereinafter simply referred to as “NMOS transistor”), and an inverter 133 and an inverter 134 connected in series.

The depletion-type NMOS transistor 131 includes a drain connected to the terminal T1, a gate, and a source connected to its own gate. The NMOS transistor 132 includes a drain connected to a gate and a source of the depletion-type NMOS transistor 131, a gate connected to the node N1, and a source connected to the terminal T2. Here, the connection point between the gate and the source of the depletion-type NMOS transistor 131 and the drain of the NMOS transistor 132 is referred to as a node N9. Between the node N9 and the node N7, the inverter 133 and the inverter 134 are connected in series.

Moreover, similar to the comparison circuit 110, the comparison circuit 120 may be configured to include an depletion-type FET (corresponding to the depletion-type NMOS transistor 131), an enhancement-type FET (corresponding to the NMOS transistor 132), and two inverters connected in series (corresponding to the inverters 133 and 134). Thus, repetitive descriptions as in the comparison circuit 110 is omitted.

Next, the operation and effects of the DC-DC converter 10 will be explained.

The DC-DC converter 10 receives power supply from the power supply circuit 60 connected to the primary side. The power supplied from the primary side is DC-DC converted (boosted) by the charge pump circuit 151 and supplied to the secondary side. The power supplied from the secondary side is supplied to and stored in the energy storage circuit 70.

The voltage VN1 appearing at the node N1 after being divided by the resistors 101, 102, 103 is input to the comparison circuit 110. The comparison circuit 110 compares the magnitude of the voltage VN1 input to the inverting input terminal (−) of the comparator 112 and the reference voltage Vref1 input to the non-inverting input terminal (+), and a first oscillation on-off control signal of a signal level corresponding to the comparison result is output from the output terminal. The comparator 112 operates as a hysteresis comparator with hysteresis characteristic in cooperation with the NMOS transistor 107.

Here, the operation of the comparator 112 will be explained with the voltage VN1 at the node N1 and the reference voltage Vref1. The comparator 112 compares the reference voltage Vref1 input to the non-inverting input terminal (+) and the voltage VN1 input to the inverting input terminal (−), and for example, in the case where VN1>Vref1, an L level first oscillation on-off control signal is output. On the other hand, in the case where VN1<Vref1, an H level first oscillation on-off control signal is output. The first oscillation on-off control signal as a second control signal is supplied to a gate of the NMOS transistor 107 and the first input port of the oscillation control circuit 152.

To explain the comparison circuit 110 at a more detailed configuration level, i.e., with the depletion-type NMOS transistor 131 and the NMOS transistor 132, the depletion-type NMOS transistor 131 operates as a constant current source for the NMOS transistor 132. Here, if K values (μ·Cox·W/L) of the depletion-type NMOS transistor 131 and the NMOS transistor 132 are made approximately equal, a gate voltage of the NMOS transistor 132 may invert the drain voltage of the NMOS transistor 132 at a substantially value (sum of an absolute value of a threshold voltage of the depletion-type NMOS transistor 131 and a threshold voltage of the NMOS transistor 132) regardless of temperature characteristic. That is, in the case where the gate voltage of the NMOS transistor 132 is larger than the sum of the absolute value of the threshold voltage of the depletion-type NMOS transistor 131 and the threshold voltage of the NMOS transistor 132, the drain voltage of the NMOS transistor 132 may be transitioned from H level to L level.

The NMOS transistor 107 switches on and off according to the signal level of the first oscillation on-off control signal supplied to the gate. In the case where the NMOS transistor 107 is on, the voltage between the terminal T1 and the terminal T2 is divided by the resistor 101 and the resistor 102. In the case where the NMOS transistor 107 is off, the voltage between the terminal T1 and the terminal T2 is divided by the resistor 101, the resistor 102, and the resistor 103.

According to the signal level of the first oscillation on-off control signal supplied to the first input port, the oscillation control circuit 152 supplies an oscillation control signal that switches on and off the oscillation circuit, i.e. between an oscillation operation state where oscillation is occurring and an oscillation stop state where oscillation is stopped (not illustrated in FIGS. 2 and 3), in the charge pump circuit 151.

The oscillation control signal includes two different signal levels, L level and H level. In the case where VN1>Vref1, for example, an H level oscillation control signal is supplied to the charge pump circuit 151. In the case where the H level oscillation control signal is supplied to the charge pump circuit 151, the oscillator circuit within the charge pump circuit 151 turns on and enters an oscillation operation state. On the other hand, in the case where VN1<Vref1, for example, an L level oscillation control signal is supplied to the charge pump circuit 151. In the case where the L level oscillation control signal is supplied to the charge pump circuit 151, the oscillator circuit within the charge pump circuit 151 turns off and enters an oscillation stop state.

In the case where a voltage Vin supplied from the power supply circuit 60 changes (rises) from a low voltage to a high voltage and reaches a voltage Vdeti+, the signal level of the voltage appearing at an output terminal of the comparator 112 transitions from H level to L level. On the other hand, in the case where the voltage supplied from the power supply circuit 60 changes (drops) from a high voltage to a low voltage and reaches a voltage Vdeti−, the signal level of the voltage appearing at the output terminal of the comparator 112 transitions from L level to H level. Here, let resistance values of the resistor 101, the resistor 102, and the resistor 103 be R101, R102, and R103 respectively, the voltage Vdeti+ and the voltage Vdeti− are expressed by the following formulae (1) and (2) with the resistance values R101, R102, and R103, and the reference voltage Vref1.

$$\begin{matrix}[ Equation 1 ] & \\ V deti += \frac{R 101 + R 102}{R 102} \times V ref 1 & ( 1 )\end{matrix}$$

$$V deti -= \frac{R 101 + R 102 + R 103}{R 102 + R 103} \times V ref 1 \qquad ( 2 )$$

Moreover, the voltage VN4 appearing at the node N4 after being divided by the resistors 104, 105, and 106 is input to the comparison circuit 120. The comparison circuit 120 compares the magnitude of the voltage VN4 input to the inverting input terminal (−) of the comparator 122 and the reference voltage Vref2 input to the non-inverting input terminal (+), and a second oscillation on-off control signal of a signal level corresponding to the comparison result is output from the output terminal. The comparator 122 operates as a hysteresis comparator with hysteresis characteristic in cooperation with the NMOS transistor 108.

Here, the operation of the comparator 122 will be explained with the voltage VN4 at the node N4 and the reference voltage Vref2. The comparator 122 compares the reference voltage Vref2 input to the non-inverting input terminal (+) and the voltage VN4 input to the inverting input terminal (−), and in the case where VN4>Vref2, for example, an L level second oscillation on-off control signal is output. On the other hand, in the case where VN4<Vref2, an H level second oscillation on-off control signal is output. The second oscillation on-off control signal as the second control signal is supplied to a gate of the NMOS transistor 108 and a second input port of the oscillation control circuit 152.

The NMOS transistor 108 switches between on and off according to the signal level of the second oscillation on-off control signal supplied to the gate. In the case where the NMOS transistor 108 is on, the voltage between the terminal T3 and the terminal T4 is divided by the resistor 104 and the resistor 105. In the case where the NMOS transistor 108 is off, the voltage between the terminal T3 and the terminal T4 is divided by the resistor 104, the resistor 105, and the resistor 106.

Similar to the case of the signal level of the first oscillation on-off control signal, the oscillation control circuit 152 provides an oscillation control signal including two different signal levels, L level and H level, according to the signal level of the second oscillation on-off control signal supplied to the second input port.

As for the oscillation control signal, in the case where VN4>Vref2, for example, the L level oscillation control signal is supplied to the charge pump circuit 151. In the case where the L level oscillation control signal is supplied to the charge pump circuit 151, the oscillation circuit in the charge pump circuit 151 turns off and enters an oscillation stop state. On the other hand, in the case where VN4<Vref2, for example, the H level oscillation control signal is supplied to the charge pump circuit 151. In the case where the H level oscillation control signal is supplied to the charge pump circuit 151, the oscillation circuit in the charge pump circuit 151 turns on and enters an oscillation operation state.

In the case where an output voltage Vout of the DC-DC converter 10, which is the voltage between the terminal T3 and the terminal T4, changes (rises) from a low voltage to a high voltage and reaches a voltage Vdeto+, the signal level of the voltage appearing at an output terminal of the comparator 122 transitions from H level to L level. On the other hand, in the case where the output voltage Vout changes (drops) from a high voltage to a low voltage and reaches a voltage Vdeto−, the signal level of the voltage at the output terminal of the comparator 122 transitions from L level to H level. Here, let resistance values of the resistor 104, the resistor 105, and the resistor 106 be R104, R105, and R106 respectively, the voltage Vdeto+ and the voltage Vdeto− are expressed by the following formulae (3) and (4) with the resistance values R104, R105, and R106, and the reference voltage Vref2.

$$\begin{matrix}[ Equation 2 ] & \\ V deto += \frac{R 104 + R 105}{R 105} \times V ref 2 & ( 3 )\end{matrix}$$

$$V deto -= \frac{R 104 + R 105 + R 106}{R 105 + R 106} \times V ref 2 \qquad ( 4 )$$

Next, as a more specific example, the following cases (i) to (iii) will be explained, namely:

(i) The power supply circuit 60 is a solar power generation device that includes a photoelectric conversion element, i.e., a solar cell pack, as an example of a power generation element.

(ii) The resistance values R101, R102, and R103 and the reference voltage Vref1 are set such that the voltage Vdeti+ is 0.55V and the voltage Vdeti− is 0.5V.

(iii) The resistance values R104, R105, and R106 and the reference voltage Vref2 are set such that the voltage Vdeto+ is 3.3V and the voltage Vdeto− is 3.0V.

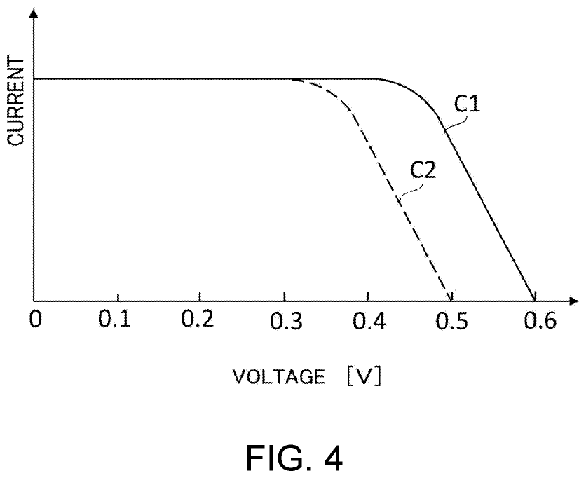

FIG. 4 is an explanatory diagram illustrating the relationship between the current (vertical axis) and the voltage (horizontal axis) of a single-cell solar cell (a characteristic diagram illustrating voltage-current characteristic).

A curve C1 (solid line) and a curve C2 (dashed line) illustrated in FIG. 4 each illustrate the voltage-current characteristic of a single-cell solar cell at temperatures of 25° C. and 50° C., respectively. As illustrated in FIG. 4, the voltage-current characteristic of a single-cell solar cell is that in the case where the temperature of the single-cell solar cell is 25° C., the maximum power (voltage×current) is reached near the battery voltage of approximately 0.5V. It is efficient to make the DC-DC converter 10 operate near the voltage capable of obtaining maximum power from the single-cell solar cell and charge the capacitive element in the energy storage circuit 70. The voltage Vdeti+ of 0.55V and the voltage Vdeti− of 0.5V are examples of voltages set near the voltage capable of obtaining maximum power.

In the case where the supply voltage from the power supply circuit 60, i.e. the voltage supplied between the terminal T1 and the terminal T2, exceeds 0.55V (=voltage Vdeti+), the H level oscillation control signal is supplied to the charge pump circuit 151, and the oscillation circuit within the charge pump circuit 151 transitions from OFF to ON. That is, the oscillation circuit enters an oscillation operation state.

In the case where the oscillation circuit is turned on and the DC-DC converter 10 operates, since the load current of the solar power generation device including the solar cell increases, the battery voltage to decreases. As the battery voltage decreases and the voltage supplied between the terminal T1 and the terminal T2 becomes less than 0.5V (=voltage Vdeti−), the L level oscillation control signal is supplied to the charge pump circuit 151, and the oscillation circuit within the charge pump circuit 151 transitions from ON to OFF. That is, the oscillation circuit enters an oscillation stop state.

In the case where the oscillation circuit is turned off and the DC-DC converter 10 stops, since the load current in the solar power generation device disappears, the battery voltage rises. As the battery voltage rises and the voltage exceeds 0.55V between the terminal T1 and the terminal T2, the oscillation circuit within the charge pump circuit 151 transitions from OFF to ON.

Moreover, in the case where the output voltage Vout of the DC-DC converter 10 changes (rises) from a low voltage to a high voltage and reaches 3.3V (=voltage Vdeto+), the L level oscillation control signal is supplied to the charge pump circuit 151, and the oscillation circuit within the charge pump circuit 151 transitions from ON to OFF. That is, the oscillation circuit enters an oscillation stop state. On the other hand, in the case where the output voltage Vout changes (drops) from a high voltage to a low voltage and reaches 3.0V (=voltage Vdeto−), the H level oscillation control signal is supplied to the charge pump circuit 151, and the oscillation circuit within the charge pump circuit 151 transitions from OFF to ON. That is, the oscillation circuit enters an oscillation operation state.

In this way, the DC-DC converter 10 operates within a range of supply voltage Vin from the power supply circuit 60, i.e. the voltage supplied between the terminal T1 and the terminal T2, being equal to or greater than 0.5V and equal to or less than 0.55V (Vdeti−≤Vin≤Vdeti+), and charges a capacitive element in the energy storage circuit 70. Moreover, the DC-DC converter 10 controls its output voltage Vout, i.e. the voltage supplied between the terminal T3 and the terminal T4, within a range of equal to or greater than 3.0V and equal to or less than 3.3V (Vdeto−≤Vout≤Vdeto+), and charges a capacitive element in the energy storage circuit 70.

In the case where a generation source of the voltage supplied from the power supply circuit 60 is a solar cell, the solar cell generally has a negative temperature characteristic (about −2 m V/° C. for single-cell solar cell). Assuming the temperature of a single-cell solar cell is 25° C. (at normal temperature environment) and the maximum power is obtained at a battery voltage of 0.5V, in the case where the temperature of the single-cell solar cell becomes higher than the normal temperature, such as 50° C., maximum power may be obtained at a battery voltage lower than the battery voltage of 0.5V (as illustrated by the curve C2 in FIG. 4).

In order to obtain the maximum power of the solar cell even in a temperature range higher than normal temperature (hereinafter simply referred to as “high temperature range”), it is necessary to give a negative temperature characteristic to the resistor 101 and make the voltage VN1 at the node N1 lower in the high temperature range than at normal temperature, or/and make the output voltage of the reference voltage circuit 113, that is, the reference voltage Vref1, have a negative temperature characteristic and be lower in the high temperature range than at normal temperature.

To give a negative temperature characteristic to the resistor 101, it suffices to apply a thermistor as the element of the resistor 101. On the other hand, to make the reference voltage Vref1 in the high temperature range lower than the reference voltage Vref1 at normal temperature, for example, it suffices to increase the K value of the NMOS transistor 132 relative to the K value of the depletion-type NMOS transistor 131. By increasing the K value of the NMOS transistor 132, a negative temperature characteristic may be given to the reference voltage Vref1 of the reference voltage circuit 113.

To configure the DC-DC converter 10 in an integrated manner, it is preferable to give a negative temperature characteristic to the reference voltage Vref1 of the reference voltage circuit 113 rather than giving a negative temperature characteristic to the resistor 101. The reason for giving a negative temperature characteristic to the reference voltage Vref1 is that it suffices to adjust the K value of the depletion-type NMOS transistor 131 and the K value of the NMOS transistor 132 in manufacturing. For example, in the case where the temperature of a single-cell solar cell is 50° C. and the battery voltage at which maximum power is obtained is around 0.4V, it suffices to give a negative temperature characteristic to the reference voltage Vref1 such that the value of the voltage Vdeti+ becomes around 0.4V.

In the case where the power generation element of the power supply circuit 60 has a negative temperature characteristic, as in the case of a solar cell, it suffices to give a negative temperature characteristic to the reference voltage Vref1. In contrast, in the case where the power generation element of the power supply circuit 60 has a positive temperature characteristic, it suffices to give a positive temperature characteristic to the reference voltage Vref1. To give a positive temperature characteristic to the reference voltage Vref1, for example, it suffices to decrease the K value of the NMOS transistor 132 relative to the K value of the depletion-type NMOS transistor 131. By reducing the K value of the NMOS transistor 132, a positive temperature coefficient may have the reference voltage Vref1 of the reference voltage circuit 113.

According to the DC-DC converter 10, the DC-DC converter 10 may be switched between the oscillation operation state (ON) and oscillation stop state (OFF) by the two comparison circuits 110 and 120. Thus, even if the DC-DC converter 10 does not include a microcontroller, the DC-DC converter 10 may be switched between the oscillation operation state (ON) and oscillation stop state (OFF), and power conversion can be efficiently performed.

Moreover, since the DC-DC converter 10 is configured to be capable of switching between the oscillation operation state (ON) and oscillation stop state (OFF) without a microcontroller, compared to a DC-DC converter having a microcontroller, the configuration is simpler and the power consumption can be significantly reduced (for example, about one digit μA).

Further, according to the DC-DC converter 10, since there is no power consumption during the operation of the microcontroller, even if the power supplied from the primary side is small, such as less than the power consumption during the operation of the microcontroller, it is possible to convert power with high efficiency. For example, in the case where the power generation element included in the power supply circuit 60 is a solar cell, the power generation capacity of the solar cell is proportional to an area of the solar cell. Thus, the DC-DC converter 10 can extract power with high efficiency even from a solar cell with a smaller area.

According to the DC-DC converter 10, at least in a temperature region where the DC-DC converter 10 is configured, by matching the temperature characteristic of the reference voltage Vref1 and the temperature characteristic of the power generation element included in the power supply circuit 60, efficient power conversion can be maintained without being affected by temperature changes. Moreover, by configuring the comparison circuit 110 to include two FETs, specifically the depletion-type NMOS transistor 131 and the NMOS transistor 132, the comparison circuit 110 can be miniaturized while the temperature characteristic of the reference voltage Vref1 and the temperature characteristic of the power generation element included in the power supply circuit 60 are matched.

Further, by applying in the boost circuit 150 the Dickson-type charge pump circuit 151 that may be configured without including a coil that is difficult to integrate, the boost circuit 150 can be miniaturized.

Thus, by making the DC-DC converter 10 include the comparison circuit 110 having the depletion-type NMOS transistor 131 and the NMOS transistor 132, as well as the boost circuit 150 having the charge pump circuit 151 without a coil, the DC-DC converter 10 can be integrated and miniaturized.

### Second Embodiment

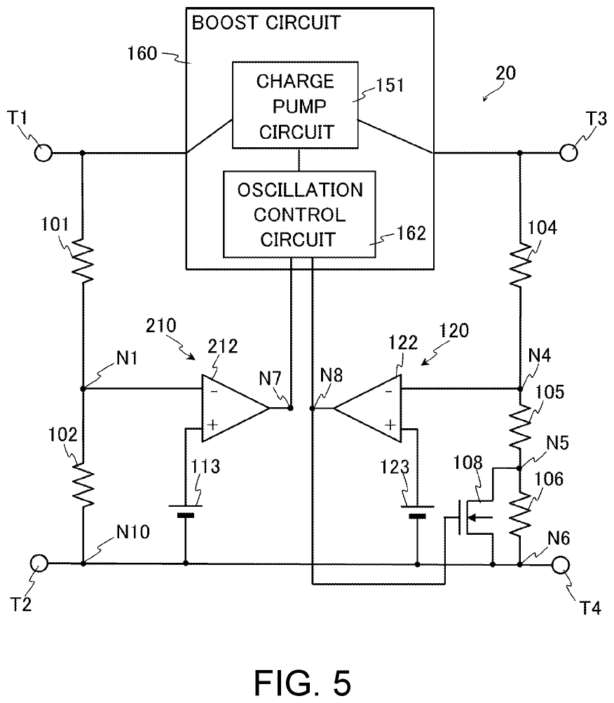

FIG. 5 is a circuit diagram of a DC-DC converter 20, which is an example of a DC-DC converter according to a second embodiment of the present invention.

The DC-DC converter 20 differs from the DC-DC converter 10 in that the resistor 103 and the NMOS transistor 107 connected between the terminal T1 and the terminal T2 are omitted, an oscillation control circuit 162 is included instead of the oscillation control circuit 152, and an error amplification circuit 210 is included instead of the comparison circuit 110, but other aspects are substantially identical. Thus, in this embodiment, the differences from the DC-DC converter 10 will be mainly described, and explanations for content substantially identical to that of the DC-DC converter 10 will be omitted.

In addition to the terminals T1 to T4, the DC-DC converter 20 further includes the charge pump circuit 151, the oscillation control circuit 162, the error amplification circuit 210, and the comparison circuit 120. The terminal T2 is connected to the terminal T4. The charge pump circuit 151 and the oscillation control circuit 162 constitute a boost circuit 160.

Between the terminal T1 and the terminal T2, the resistor 101 and the resistor 102 are connected in series from the terminal T1 to the terminal T2 to form a resistor voltage divider circuit. Here, the connection point between a second port of the resistor 102 and the terminal T2 is referred to as a node N10.

The error amplification circuit 210 is a circuit that includes a first input terminal, a second input terminal, and an output terminal and that amplifies the difference between the reference voltage Vref1 input to the first input terminal and the voltage VN1 input to the second input terminal and outputs it from the output terminal.

The error amplification circuit 210 includes an error amplifier 212, and the reference voltage circuit 113 as the first reference voltage circuit. The error amplifier 212 includes an inverting input terminal (−) connected to the node N1, a non-inverting input terminal (+) receiving supply of the reference voltage Vref1, and an output terminal connected to the node N7, which is an output terminal of the error amplification circuit 210. The reference voltage circuit 113 includes an output port that is connected to the non-inverting input terminal (+) of the error amplifier 212 and that supplies the reference voltage Vref1 to the non-inverting input terminal (+) of the error amplifier 212.

The oscillation control circuit 162 includes a first input port connected to the node N7, a second input port connected to the node N8, and the output port connected to the control port of the charge pump circuit 151. Functionally, the oscillation control circuit 162 has an oscillation switching function that switches between an oscillation operation state and an oscillation stop state, that is, on and off of oscillation, and an oscillation frequency adjustment function that adjusts the oscillation frequency within a predetermined range.

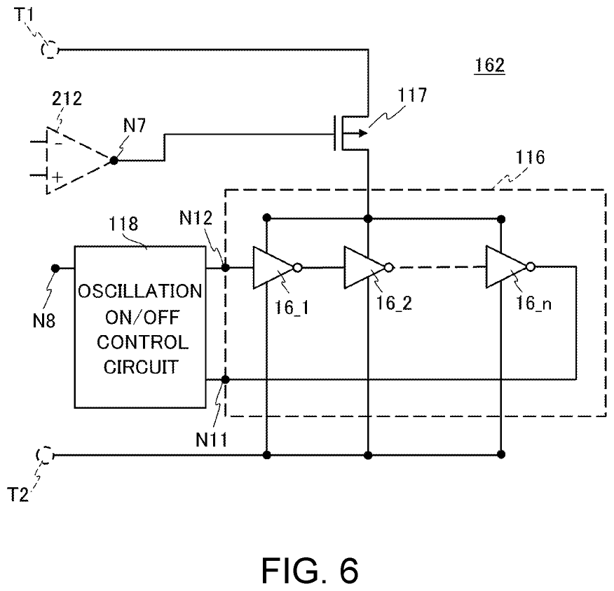

FIG. 6 is a circuit diagram illustrating an example of the oscillation control circuit 162.

The oscillation control circuit 162 includes a PMOS transistor 117 as a control transistor for controlling the power supply voltage supplied to a ring oscillator 116, and an oscillation on-off control circuit 118.

The ring oscillator 116 as an oscillation circuit in the charge pump circuit 151 includes n (n is an odd number) inverters 16_1, 16_2, . . . , 16_n connected in a ring shape. Power supply terminals of the inverters 16_1, 16_2, . . . , 16_n are respectively connected to a drain of the PMOS transistor 117. The ground terminals of the inverters 16_1, 16_2, . . . , 16_n are connected to the terminal T2.

The PMOS transistor 117 includes a gate connected to an output terminal of the error amplifier 212, a source connected to the terminal T1, and a drain connected to each power supply terminal of the inverters 16_1, 16_2, . . . , 16_n.

The oscillation on-off control circuit 118 includes: a control signal input port connected to an output port of the comparison circuit 120, namely the node N8; an input port connected to an output port of the final stage inverter 16_n, namely a node N11; and an output terminal connected to an input port of the first stage inverter 16_1, namely a node N12. The oscillation on-off control circuit 118 is configured to be capable of switching whether or not to invert the signal level of the signal received from the input port from L level to H level or from H level to L level and output it from the output port, according to the signal level of the second oscillation on-off control signal that is received by the control signal input port.

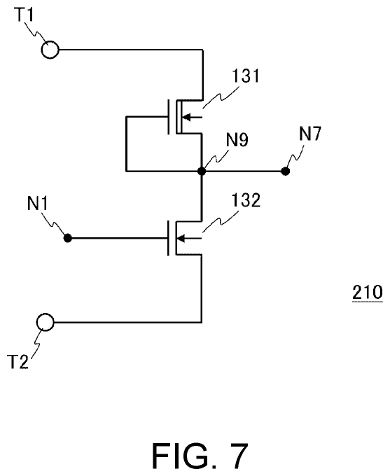

FIG. 7 is a circuit diagram illustrating an example of the error amplification circuit 210 included in a DC-DC converter according to a second embodiment.

The error amplification circuit 210 is configured, for example, with the depletion-type NMOS transistor 131 and the NMOS transistor 132. The depletion-type NMOS transistor 131 includes the drain connected to the terminal T1, a gate, and a source connected to its own gate. The NMOS transistor 132 includes a drain connected to the gate and the source of the depletion-type NMOS transistor 131, a gate connected to the node N1, and a source connected to the terminal T2.

Next, the operation and effects of the DC-DC converter 20 will be described, focusing on content that differs from the operation and effects of the DC-DC converter 10.

The voltage VN1 appearing at the node N1 after being divided by the resistors 101 and 102 is input to the error amplification circuit 210. In the error amplification circuit 210, the difference between the reference voltage Vref1 input to the non-inverting input terminal (+) of the error amplifier 212 and the voltage VN1 input to the inverting input terminal (−) of the error amplifier 212 is amplified, and a voltage Vel is output from the output terminal.

As for the error amplifier 212, in the case where the voltage VN1 input to the inverting input terminal (−) is higher than the reference voltage Vref1 input to the non-inverting input terminal (+), i.e. in the case where Vref1−VN1<0, the voltage Vel appearing at the output terminal of the error amplifier 212 decreases. On the other hand, in the case where the reference voltage Vref1 input to the non-inverting input terminal (+) is higher than the voltage VN1 input to the inverting input terminal (−), i.e. in the case where Vref1−VN1>0, the voltage Vel appearing at the output terminal of the error amplifier 212 increases. The voltage Vel is output from the node N7, which is an output terminal, as an oscillation frequency control signal.

The oscillation control circuit 162 receives an oscillation frequency control signal as a second control signal at its first input port. In the case where the oscillation control circuit 162 receives an oscillation frequency control signal at its first input port, a gate voltage of the PMOS transistor 117 increases or decreases according to the level of voltage of the oscillation frequency control signal, and thus the drain current of the PMOS transistor 117 increases or decreases. In the case where the voltage of the oscillation frequency control signal, i.e. the voltage Vel, decreases, the PMOS transistor 117 allows more current to flow, and thus the oscillation frequency of the ring oscillator 116 increases.

In the case where the oscillation frequency of the ring oscillator 116 increases, since the DC-DC converter 20 requires more power from the power supply circuit 60, the load current of the power supply circuit 60 increases. In the case where the generation source of voltage supplied from the power supply circuit 60 is a solar cell, according to the voltage-current characteristic of the solar cell, as the load current of the solar cell increases, the battery voltage decreases, and the voltage VN1 decreases. As the voltage VN1 decreases, the voltage Vel increases.

On the other hand, as the voltage Vel increases, the PMOS transistor 117 throttles the drain current, and thus the oscillation frequency of the ring oscillator 116 decreases. As the voltage Vel further increases, the oscillation of the ring oscillator 116 eventually stops.

As the oscillation frequency of the ring oscillator 116 decreases, the DC-DC converter 20 requires less power, and thus the load current of the power supply circuit 60 decreases. In the case where the generation source of voltage supplied from the power supply circuit 60 is a solar cell, according to the voltage-current characteristic of the solar cell, as the load current of the solar cell decreases, the battery voltage increases. As the voltage VN1 increases, the voltage Vel decreases.

Thus, in the case where the generation source of voltage supplied from the power supply circuit 60 is a solar cell, the charge pump circuit 151 is controlled to operate at an oscillation frequency that the voltage VN1 and the reference voltage Vref1 are equal. A battery voltage Vsol of the solar cell is expressed by the following formula (5) with the resistance values R101 and R102, and the reference voltage Vref1.

$$\begin{matrix}[ Equation 3 ] & \\ V sol += \frac{R 101 + R 102}{R 102} \times V ref 1 & ( 5 )\end{matrix}$$

For example, in the case where the resistance values R101 and R102 and the reference voltage Vref1 are set to make the battery voltage Vsol=0.5V, the DC-DC converter 20 controls the oscillation frequency of the ring oscillator 116 to make the battery voltage Vsol be 0.5V.

Moreover, the oscillation control circuit 162 receives a second oscillation on-off control signal at a second input port. In the case where the oscillation control circuit 162 receives a second oscillation on-off control signal at its second input port, it switches between on and off of oscillation, similar to the oscillation control circuit 152. That is, in the case where the signal level of the second oscillation on-off control signal is a signal level indicating VN4>Vref2, the oscillation control circuit 162 supplies an oscillation control signal that turns off the oscillation operation to the control port of the charge pump circuit 151; on the other hand, in the case where it is a signal level indicating VN4<Vref2, an oscillation control signal for turning on the oscillation operation is supplied to the control port of the charge pump circuit 151.

To explain the operation within the oscillation control circuit 162 in more detail, in the oscillation control circuit 162, a second oscillation on-off control signal is received from the control signal input port of the oscillation on-off control circuit 118. The oscillation on-off control circuit 118 controls whether or not to stop oscillation by inverting the signal level of the signal received from the input port or to oscillate without inverting the signal level of the signal received from the input port, according to the signal level of the second oscillation on-off control signal received at the control signal input port. By the above operation of the oscillation on-off control circuit 118, the oscillation of the ring oscillator 116 are switched on and off.

According to the DC-DC converter 20, it is possible to switch between the oscillation operation state (ON) and the oscillation stop state (OFF) of the DC-DC converter 20 by the error amplification circuit 210 and the comparison circuit 120. Thus, even if the DC-DC converter 20 does not include a microcontroller, it is also possible to switch between the oscillation operation state and the oscillation stop state of the DC-DC converter 20, and power can be converted efficiently.

Moreover, since the DC-DC converter 20 is configured to be capable of switching between an oscillation operation state and an oscillation stop state without a microcontroller, compared to a DC-DC converter having a microcontroller, the configuration is simpler and the power consumption can be significantly reduced (for example, about one digit μA).

Further, according to the DC-DC converter 20, since there is no power consumption during the operation of the microcontroller, even if power supplied from the primary side is small power, such as less than the power consumption during the operation of the microcontroller, it is possible to convert power at high efficiency. For example, in the case where the power generation element included in the power supply circuit 60 is a solar cell, it is possible to extract power at high efficiency even from a solar cell with a smaller area.

According to the DC-DC converter 20, at least in a temperature region where the DC-DC converter 20 is configured, by matching the temperature characteristic of the reference voltage Vref1 and the temperature characteristic of the power generation element included in the power supply circuit 60, efficient power conversion can be maintained without being affected by temperature changes. Moreover, by configuring the error amplification circuit 210 to include two FETs, specifically the depletion-type NMOS transistor 131 and the NMOS transistor 132, the error amplification circuit 210 can be miniaturized while the temperature characteristic of the reference voltage Vref1 and the temperature characteristic of the power generation element included in the power supply circuit 60 are matched.

Further, by applying in the boost circuit 150 the Dickson-type charge pump circuit 151 that may be configured without including a coil that is difficult to integrate, the boost circuit 150 can be miniaturized.

Thus, by making the DC-DC converter 20 include the error amplification circuit 210 having the depletion-type NMOS transistor 131 and the NMOS transistor 132, as well as the boost circuit 160 having the charge pump circuit 151 without a coil, the DC-DC converter 20 can be integrated and miniaturized.

The present invention is not limited to the above embodiments as they are, and at the implementation stage, it may be implemented in various forms other than the above embodiments, and various omissions, additions, replacements or changes may be made within the scope not departing from the gist of the invention. These embodiments and their modifications are included in the scope and gist of the invention, as well as in the scope of the invention described in the claims and its equivalences.

What is claimed is:

1. A DC-DC converter, comprising:
a first input terminal, a second input terminal, a first output terminal, and a second output terminal;
a charge pump circuit, comprising an oscillation circuit and provided between the first input terminal and the first output terminal;
a first control circuit, comprising a first comparator that has a hysteresis characteristic and outputs a signal comprising two signal levels based on a magnitude relationship between a voltage proportional to an output voltage between the first output terminal and the second output terminal and a first reference voltage, and generating a first control signal that controls switching of the signal between ON and OFF of an oscillation operation of the oscillation circuit; and
a second control circuit, outputting a signal based on a voltage proportional to an input voltage between the first input terminal and the second input terminal and a second reference voltage as a second control signal that controls the oscillation operation of the oscillation circuit.

2. The DC-DC converter according to claim 1,
wherein the second control circuit comprises a second comparator that outputs a signal comprising two signal levels based on a magnitude relationship between the voltage proportional to the input voltage and the first reference voltage as the second control signal, and
the second control signal is a control signal that controls switching between ON and OFF of the oscillation operation of the oscillation circuit.

3. The DC-DC converter according to claim 2, wherein the second comparator is a hysteresis comparator having a hysteresis characteristic.

4. The DC-DC converter according to claim 1, wherein the second control circuit comprises an error amplifier that outputs a signal that amplifies a difference between the voltage proportional to the input voltage and the first reference voltage, and outputs a signal output from the error amplifier as the second control signal that controls an oscillation frequency of the oscillation circuit.

5. The DC-DC converter according to claim 4,
wherein a range of the oscillation frequency of the oscillation circuit that the second control circuit controls comprises 0 Hertz; and
the signal output from the error amplifier is output as the second control signal that controls switching between ON in which the oscillation circuit oscillates at a predetermined oscillation frequency and OFF in which the oscillation frequency is in a non-oscillating state of 0 Hertz.

6. The DC-DC converter according to claim 4, wherein the second control circuit is configured to be capable of generating the second control signal in which the oscillation frequency of the oscillation circuit increases as a voltage input to the first input terminal and the second input terminal increases, and the oscillation frequency of the oscillation circuit decreases as to the voltage input to the first input terminal and the second input terminal decreases.

7. The DC-DC converter according to claim 1, wherein at least one of the first control circuit and the second control circuit comprises two field-effect transistors.

8. The DC-DC converter according to claim 1,
wherein the second control circuit comprises a reference voltage circuit that generates the second reference voltage; and
the reference voltage circuit has a temperature characteristic matched with a temperature characteristic of a power generation element comprised in a circuit connected to the first input terminal and the second input terminal.
